(19) United States
(12) Patent Application Publication
(10) Pub. No.: US 2026/0029194 A1
(43) Pub. Date: Jan. 29, 2026

(54) SUBSTRATE TREATMENT APPARATUS AND METHOD

(71) Applicant: DEVICE CO., LTD., Chungcheongnam-do (KR)

(72) Inventor: Taek Youb Lee, Cheonan-si (KR)

(73) Assignee: DEVICE CO., LTD., Chungcheongnam-do (KR)

(21) Appl. No.: 19/000,120

(22) Filed: Dec. 23, 2024

(30) Foreign Application Priority Data
Jul. 24, 2024 (KR) 10-2024-0098089

(51) Int. Cl. F26B 3/28; B08B 3/04; B08B 3/10; H01L 21/67

(52) U.S. Cl. CPC F26B 3/28; B08B 3/041; B08B 3/10; H01L 21/67034; H01L 21/67051

(57) ABSTRACT

The present disclosure relates to a substrate treatment apparatus including: a substrate-holding unit for holding and rotating a substrate; a treatment liquid feed unit for feeding treatment liquid to a top of the substrate; a rinsing liquid feed unit for feeding rinsing liquid to the top of the substrate; a drying liquid feed unit located to reciprocate horizontally above the substrate in such a way as to feed drying liquid to a drying liquid injection nozzle, in a state where the entire top region of the substrate is covered with the rinsing liquid, to allow the rinsing liquid to be replaced with the drying liquid; and a heating unit located under the substrate to heat the substrate.

### CROSS REFERENCE TO RELATED APPLICATION OF THE DISCLOSURE

The present application claims the benefit of Korean Patent Application No. 10-2024-0098089 filed in the Korean Intellectual Property Office on Jul. 24, 2024, the entire contents of which are incorporated herein by reference.

### BACKGROUND OF THE DISCLOSURE

### Field of the Disclosure

The present disclosure relates to a substrate treatment apparatus and method, more specifically to a substrate treatment apparatus and method that is capable of effectively preventing patterns formed on a substrate from leaning on each other in a process of rinsing and drying the substrate.

### Background of the Related Art

Generally, a substrate treatment apparatus is an apparatus that performs, with the use of treatment liquids, various processes such as deposition, photolithography, etching, and cleaning for substrates such as semiconductor wafers, display substrates, optical disk substrates, magnetic disk substrates, photomask substrates, ceramic substrates, solar cell substrates, and the like.

Among them, the cleaning is carried out to remove foreign substances or particles from the substrate, and representatively, the cleaning includes a process of feeding rinsing liquid and drying liquid to top or underside of the substrate, while the substrate is rotating at a high speed in a state of being supportedly placed on top of a chuck base (spin head).

If the rinsing liquid with relatively high surface tension, which is made of deionized water or carbonated water, remains on the high-integration micropatterned semiconductor substrate, neighboring patterns on the substrate pull each other and thus lean on each other, which causes a defect (hereinafter, referred to as “leaning” and see FIG. 1A to 1C).

As shown in FIGS. 1A and 1B, if the rinsing liquid remains, the neighboring patterns lean on each other, thereby causing the leaning, and FIG. 1C is an examplary 3D image showing a state where the leaning occurs on a substrate.

To solve such a leaning problem, in conventional technologies, drying liquid with low surface tension, such as isopropyl alcohol (IPA), which is easily mixed with the rinsing liquid and has high volatility, is fed to the substrate and replaces the rinsing liquid applied to the substrate, but in the case of micropatterned substrates, such conventional technologies still fail to reduce the leaning to a desired level.

Recently, a heating unit is located under the substrate to allow the replaced drying liquid to be quickly volatilized, thereby effectively suppressing the occurrences of leaning.

However, there is not enough to reduce the leaning occurring on substrates with patterns more micronized day by day only through the supply of the rinsing liquid and the drying liquid, while the underside of the substrate is being simply heated.

### SUMMARY OF THE DISCLOSURE

Accordingly, the present disclosure has been made in view of the above-mentioned problems occurring in the related art, and it is an object of the present disclosure to provide a substrate treatment apparatus and method that is capable of effectively reducing the occurrences of leaning between neighboring patterns on a substrate in a process of cleaning the substrate, thereby ensuring a high yield for the substrate.

To accomplish the above-mentioned objects, according to one aspect of the present disclosure, there is provided a substrate treatment apparatus including: a substrate-holding unit for holding and rotating a substrate; a treatment liquid feed unit for feeding treatment liquid to a top of the substrate; a rinsing liquid feed unit for feeding rinsing liquid to the top of the substrate; a drying liquid feed unit located to reciprocate horizontally above the substrate in such a way as to feed drying liquid through a drying liquid injection nozzle, in a state where the entire top region of the substrate is covered with the rinsing liquid, to allow the rinsing liquid to be replaced with the drying liquid; and a heating unit located under the substrate to heat the substrate.

According to the present disclosure, desirably, while the substrate is being heated by means of the heating unit, the drying liquid may be fed to the substrate through the drying liquid injection nozzle to allow the rinsing liquid to be replaced therewith, and while the substrate on which the rinsing liquid is replaced with the drying liquid is being heated, the drying liquid injection nozzle may move from a central portion to a peripheral portion of the substrate to feed the drying liquid to the substrate.

According to the present disclosure, desirably, while the substrate is being heated by means of the heating unit, the rinsing liquid may be fed to the substrate by means of the rinsing liquid feed unit.

According to the present disclosure, desirably, after the drying liquid injection nozzle stops on the central portion of the substrate for a given period of time and feeds the drying liquid to the substrate to allow the rinsing liquid to be replaced with the drying liquid, the drying liquid injection nozzle may move from the central portion to the peripheral portion of the substrate.

According to the present disclosure, desirably, the time during which the drying liquid injection nozzle feeds the drying liquid to the substrate in the state where the drying liquid injection nozzle stops on the central portion of the substrate may be in the range between 10 and 120 seconds.

According to the present disclosure, desirably, the drying liquid fed to the substrate may have a temperature greater than or equal to 50° C. and less than a boiling point thereof.

According to the present disclosure, desirably, the moving speed of the drying liquid injection nozzle from the central portion to the peripheral portion of the substrate may become gradually fast.

According to the present disclosure, desirably, while the drying liquid injection nozzle is moving from the central portion to the peripheral portion of the substrate, a flow rate of the drying liquid discharged when the drying liquid injection nozzle reaches the peripheral portion of the substrate may be in the range of 50 to 80% of a flow rate of the drying liquid discharged when the drying liquid injection nozzle is located on the central portion of the substrate.

To accomplish the above-mentioned objects, according to another aspect of the present disclosure, there is provided a substrate treatment method comprising: feeding treatment liquid to a top of a substrate rotating; treating the top of the substrate with rinsing liquid; feeding drying liquid to the substrate through a drying liquid injection nozzle, while the substrate is being heated in a state where the entire top region of the substrate is covered with the rinsing liquid, to allow the rinsing liquid to be replaced with the drying liquid; and while the substrate on which the rinsing liquid is replaced with the drying liquid is being heated, moving the drying liquid injection nozzle from a central portion to a peripheral portion of the substrate to feed the drying liquid to the substrate.

According to the present disclosure, desirably, in the treating the top of the substrate with rinsing liquid, the rinsing liquid may be fed, while the substrate is being heated.

According to the present disclosure, desirably, after the drying liquid injection nozzle stops on the central portion of the substrate for a given period of time, while feeding the drying liquid to the substrate, the drying liquid injection nozzle may move from the central portion to the peripheral portion of the substrate.

According to the present disclosure, desirably, the time during which the drying liquid injection nozzle feeds the drying liquid to the substrate in the state where the drying liquid injection nozzle stops on the central portion of the substrate may be in the range between 10 and 120 seconds.

According to the present disclosure, desirably, the drying liquid fed to the substrate may have a temperature greater than or equal to 50° C. and less than a boiling point thereof.

According to the present disclosure, desirably, the moving speed of the drying liquid injection nozzle from the central portion to the peripheral portion of the substrate may become gradually fast.

According to the present disclosure, desirably, while the drying liquid injection nozzle is moving from the central portion to the peripheral portion of the substrate, a flow rate of the drying liquid discharged when the drying liquid injection nozzle reaches the peripheral portion of the substrate may be in the range of 50 to 80% of a flow rate of the drying liquid discharged when the drying liquid injection nozzle is located on the central portion of the substrate.

According to the present disclosure, desirably, the treating the top of the substrate with rinsing liquid may be carried out to feed the rinsing liquid to the substrate and rinse the substrate, while a rotational speed of the substrate is being kept to a speed of 200 to 1000 RPM, and to then feed the rinsing liquid in a state where the rotational speed of the substrate decreases to a speed less than or equal to 100 RPM, and the replacing the rinsing liquid with the drying liquid may be carried out to feed the drying liquid to the top of the substrate, while the rotational speed of the substrate is being kept to a speed less than or equal to 300 RPM.

According to the present disclosure, desirably, the replacing the rinsing liquid with the drying liquid may be carried out to replace the rinsing liquid with the drying liquid, while the rotational speed of the substrate is being kept to a speed less than or equal to 100 RPM after the drying liquid injection nozzle has been located on the center of the substrate, and thus to complete the replacement, while the rotational speed of the substrate increases to a speed greater than 100 RPM and less than or equal to 300 RPM.

### BRIEF DESCRIPTION OF THE DRAWINGS

The above and other objects, features and advantages of the present disclosure will be apparent from the following detailed description of the embodiments of the disclosure in conjunction with the accompanying drawings, in which:

FIG. 1A is a sectional view showing initial state before neighboring patterns lean on each other;

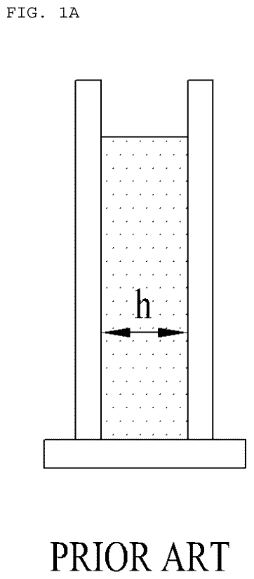

FIG. 1B is a sectional view showing state where neighboring patterns lean on each other;

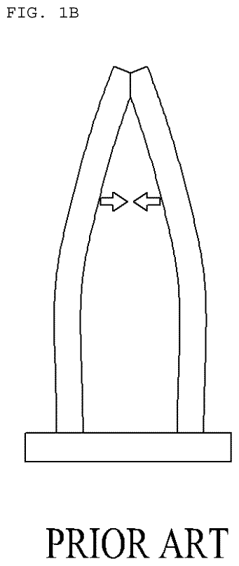

FIG. 1C an image obtained by capturing a state where leaning occurs on a substrate;

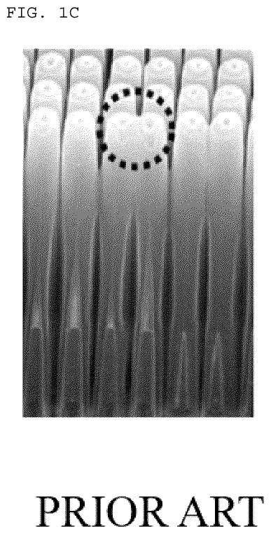

FIG. 2 is a sectional view showing a substrate treatment method through a substrate treatment apparatus according to the present disclosure;

FIG. 3 is an exemplary view showing radial positions on the substrate according to the present disclosure;

FIG. 4 is an experimental graph showing the comparison results of qualities of substrates through the number of leaning occurrences among a case in which drying liquid is fed only to the central portion of the substrate and then dried, without allowing the substrate to be heated through a heating unit located under the substrate, a case in which the substrate is dried, while a drying liquid injection nozzle is moving from the central portion to the peripheral portion of the substrate, without allowing the substrate to be heated, and a case in which the substrate is dried according to the present disclosure, while the substrate is being heated and the drying liquid injection nozzle is moving from the central portion to the peripheral portion of the substrate;

FIG. 5 is a graph showing experimental results wherein the number of leaning occurrences is varied according to the feed time of the drying liquid to the central portion of the substrate before the drying liquid injection nozzle moves from the central portion to the peripheral portion of the substrate;

FIG. 6 is a graph showing comparison results of the number of leaning occurrences in cases where the drying liquid fed through the drying liquid injection nozzle has temperatures of 23° C., 50° C., and 70° C.;

FIG. 7A is a graph showing variations in a transversely moving speed of the drying liquid injection nozzle from the central portion to the peripheral portion of the substrate;

FIG. 7B is a graph showing variations in the number of leaning occurrences according to changes in the moving speed of the drying liquid injection nozzle from the central portion to the peripheral portion of the substrate;

FIG. 8 is a graph showing comparison results of the variations in the number of leaning occurrences in the case, while the drying liquid injection nozzle is moving from the central portion to the peripheral portion of the substrate, where a flow rate of the drying liquid discharged when the drying liquid injection nozzle reaches the central portion of the substrate and a flow rate of the drying liquid discharged when the drying liquid injection nozzle is located on the peripheral portion of the substrate are constant and gradually decrease respectively; and

FIG. 9 is a graph showing the comparison results of the number of leaning occurrences in the case where the drying liquid is fed, while the substrate is rotating to a low rotational speed less than or equal to 100 RPM and in the case where the drying liquid is fed, while the substrate is rotating to a high rotational speed greater than or equal to 500 RPM, after the treatment of the rinsing liquid.

### DETAILED DESCRIPTION OF THE PREFERRED EMBODIMENT

Hereinafter, an embodiment of the present disclosure will be explained in detail with reference to the attached drawings.

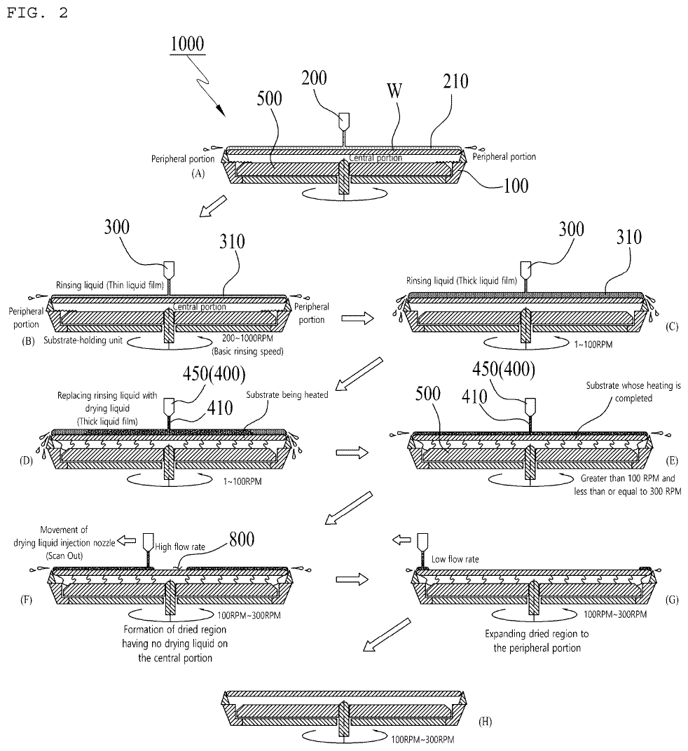

As shown in FIG. 2, a substrate treatment apparatus 1000 according to the present disclosure includes: a substrate-holding unit 100 for holding and rotating a substrate W; a treatment liquid feed unit 200 for feeding treatment liquid 210 to a top of the substrate W; a rinsing liquid feed unit 300 for feeding rinsing liquid 310 to the top of the substrate W; a drying liquid feed unit 400 located to reciprocate horizontally above the substrate W in such a way as to feed drying liquid 410 through a drying liquid injection nozzle 450, in a state where the entire top region of the substrate W is covered with the rinsing liquid 310, to allow the rinsing liquid 310 to be replaced with the drying liquid 410; and a heating unit 500 located under the substrate W to heat the substrate W.

The heating unit 500 consists of various heating lamps as known, such as LEDs, an IR lamps, and the like.

In this case, the drying liquid feed unit 400 is located movable horizontally from a central portion to a peripheral portion of the substrate W by means of an appropriate guide mechanism (not shown) such as a guide beam, so that while the substrate W is being heated by means of the heating unit 500, the drying liquid feed unit 400 feeds the drying liquid 410 through the drying liquid injection nozzle 450, thereby performing the replacement of the rinsing liquid 310 with the drying liquid 410. While the substrate W on which the rinsing liquid 310 has been replaced with the drying liquid 410 is being heated, further, the drying liquid feed unit 400 moves from the central portion to the peripheral portion of the substrate W, while feeding the drying liquid 410 through the drying liquid injection nozzle 450, thereby forming a dried region 800 on the central portion of the substrate W. For reference, through the replacement of the rinsing liquid 310, the drying liquid 410 having low surface tension replaces the rinsing liquid 310 so that the drying liquid 410 is dried to prevent leaning from occurring.

In detail, while the substrate W is being heated by the heating unit 500 and the drying liquid injection nozzle 450 is moving from the central portion to the peripheral portion of the substrate W, above the substrate W on which the rinsing liquid 310 has been replaced with the drying liquid 410, the dried region 800 on the substrate W is exposed to the outside so that leaning can be suppressed through perfect dry having no residual liquid.

While the rinsing liquid 310 is being fed to the substrate W by means of the rinsing liquid feed unit 300, the substrate W may be heated by means of the heating unit 500.

In detail, before the rinsing liquid 310 is replaced with the drying liquid 410 fed to the substrate W, the underside of the substrate W is pre-heated, so that the rinsing liquid 310 is mixed smoothly with the drying liquid 410 in next replacement process and a volatile reaction occurs more quickly, thereby reducing the time for treating the process.

Further, after the drying liquid injection nozzle 450 temporarily stops on the central portion of the substrate W for a given period of time to allow the rinsing liquid 310 to be replaced with the drying liquid 410, the drying liquid injection nozzle 450 moves from the central portion to the peripheral portion of the substrate W.

This is a process of allowing the entire top region of the substrate W to be replaced with the drying liquid 410, which is carried out for a period of time in the range between about 10 and 120 seconds.

If the stop time is too short, the replacement effect is not sufficiently obtained, and contrarily, if the stop time is too long, the time for treating the process becomes long, without any additional effects.

Further, the drying liquid 410 fed to the substrate W desirably has a temperature greater than or equal to 50° C. and less than a boiling point thereof, which ensures leaning reduction effects.

Under experiments, the higher a temperature of the drying liquid 410 is, the less leaning happens, but if the drying liquid 410 is boiled, it is vaporized and has air bubbles formed therein. The air bubbles permeate into the patterns covered with the rinsing liquid 310 and obstruct the replacement of the rinsing liquid 310 present between patten capacitors with the drying liquid 410, so that unexpected unspecified leaning may happen, thereby undesirably increasing a defect rate of the substrate.

Further, the moving speed of the drying liquid injection nozzle 450 from the central portion to the peripheral portion of the substrate W desirably becomes fast gradually, thereby reducing the time for treating the process and increasing the productivity thereof.

Furthermore, while the drying liquid injection nozzle 450 is moving from the central portion to the peripheral portion of the substrate W, a flow rate of the drying liquid 410 discharged when the drying liquid injection nozzle 450 reaches the peripheral portion of the substrate W is desirably in the range of 50 to 80% of a flow rate of the drying liquid 410 discharged when the drying liquid injection nozzle 450 is located on the central portion of the substrate W, thereby reducing an amount of drying liquid 410 used and lowering a cost for operating equipment.

Hereinafter, an of explanation a substrate treatment method using the above-mentioned substrate treatment apparatus 1000 according to the present disclosure will be given in detail.

A substrate treatment method according to the present disclosure comprises: feeding the treatment liquid to the top of the substrate W rotating; treating the top of the substrate W with the rinsing liquid 310; feeding the drying liquid 410 to the substrate W through the drying liquid injection nozzle 450, in a state where the entire top region of the substrate W is covered with the rinsing liquid 310, while the substrate W is being heated, to allow the rinsing liquid 310 to be replaced with the drying liquid 410; and while the substrate W on which the rinsing liquid 310 has been replaced with the drying liquid 410 is being heated, moving the drying liquid injection nozzle 450 from the central portion to the peripheral portion of the substrate W to feed the drying liquid to the substrate W.

In this case, while the substrate W is being heated, the drying liquid 410 is fed through the drying liquid injection nozzle 450 to perform the replacement of the rinsing liquid 310 therewith, and while the substrate W on which the rinsing liquid 310 has been replaced with the drying liquid 410 is being heated, the drying liquid injection nozzle 450 moves from the central portion to the peripheral portion of the substrate W to feed the drying liquid 410 to the substrate W, thereby forming the dried region 800 extending from the central portion of the substrate W.

In detail, while the substrate W is being heated, the drying liquid injection nozzle 450 is moving from the central portion to the peripheral portion of the substrate W, above the substrate W on which the rinsing liquid 310 has been replaced with the drying liquid 410, so that the dried region 800 on the substrate W is exposed to the outside, thereby ensuring leaning reduction through perfect dry having no residual liquid.

While the substrate W is being heated, it is kept to a temperature in the range between 75 and 200° C.

If the substrate W is heated to a temperature less than 75° C., the heating effect is not sufficiently obtained, and contrarily, if the substrate W is heated to a temperature greater than 200° C., the drying liquid 410 is accumulated in temperature, while moving from the central portion to the peripheral portion of the substrate W, so that the vaporization of the drying liquid 410 may happen.

To prevent such vaporization from happening, a flow rate of the drying liquid 410 increases to allow a thickness of the drying liquid 410 to increase, but in this case, the amount of drying liquid used suddenly increases to cause the cost for operating the equipment to be undesirably raised.

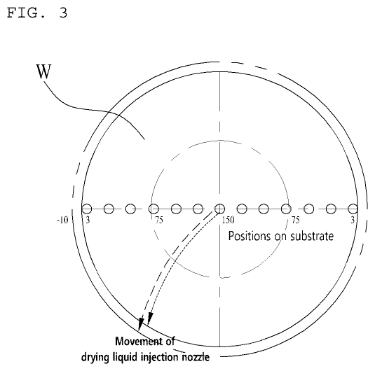

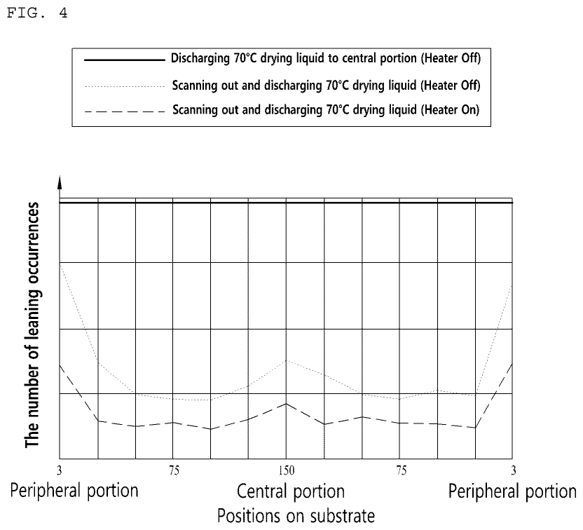

FIG. 4 is an experimental graph showing the comparison results of qualities of substrates through the number of leaning occurrences among a case in which the drying liquid 410 is fed only to the central portion of the substrate W and then dried, without allowing the substrate W to be heated through the heating unit 500 located under the substrate W, a case in which the substrate W is dried, while the drying liquid injection nozzle 450 is moving from the central portion to the peripheral portion of the substrate W, without allowing the substrate W to be heated, and a case in which the substrate W is dried, while the substrate W is being heated and the drying liquid injection nozzle 450 is moving from the central portion to the peripheral portion of the substrate W. On the conditions of the three cases, the drying liquids have a temperature of 70° C., and the radial positions on top of the substrate W are shown in FIG. 3.

As shown, in the case where the drying liquid is fed only to the central portion of the substrate W and then dried, without allowing the substrate W to be heated through the heating unit 500 located under the substrate W, it is found that substantially numerous leaning occurs over the entire region of the substrate W, and in the case where the substrate W is dried, while the drying liquid injection nozzle 450 is moving from the central portion to the peripheral portion of the substrate W, without allowing the substrate W to be heated, it is found that the number of leaning occurrences is greatly reduced, but a lot of leaning still occurs on the peripheral portion of the substrate W. In the case where in which the substrate W is dried, while the substrate W is being heated in the initial stage (Please refer to FIG. 2) of the process and the drying liquid injection nozzle 450 is moving from the central portion to the peripheral portion of the substrate W, it is found that the number of leaning occurrences is greatly reduced.

In the stage of treating the top of the substrate W with the rinsing liquid 310, the rinsing liquid 310 is fed to the substrate W, while the substrate W is being heated.

As a result, before the rinsing liquid 310 is replaced with the drying liquid 410 fed to the substrate W, the rinsing liquid 310 is fed to the substrate W, while the underside of the substrate W is being heated, so that the rinsing liquid 310 is mixed smoothly with the drying liquid 410 in next replacement process and a volatile reaction occurs more quickly, thereby reducing the time for treating the process.

Before the drying liquid injection nozzle 450 moves from the central portion to the peripheral portion of the substrate W, further, the drying liquid injection nozzle 450 temporarily stops on the central portion of the substrate W for a given period of time, while feeding the drying liquid 410 to the substrate W, and next, it desirably moves from the central portion to the peripheral portion of the substrate W.

This is a process of allowing the entire top region of the substrate W to be completely replaced with the drying liquid 410, which is carried out for a given period of time in the range between about 10 and 120 seconds.

If the stop time is too short, the replacement effect is not sufficiently obtained, and contrarily, if the stop time is too long, the time for treating the process just extends, without any additional effects.

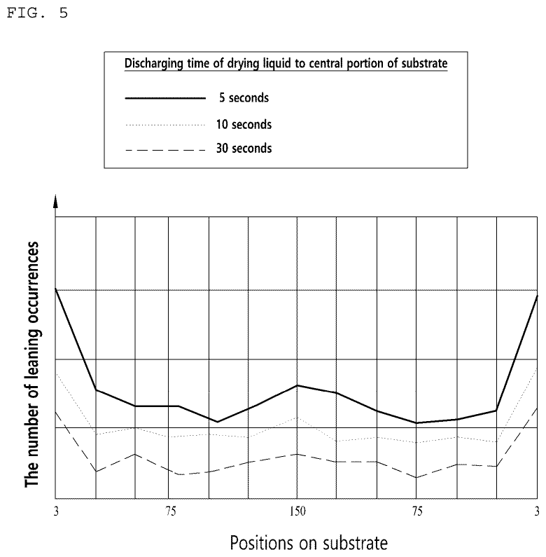

FIG. 5 is a graph showing experimental results wherein the number of leaning occurrences is varied according to the feed time of the drying liquid 410 to the central portion of the substrate W before the drying liquid injection nozzle 450 moves from the central portion to the peripheral portion of the substrate W.

As shown, the longer the feed time increases to 5, 10, and 30 seconds, the smaller the number of leaning occurrences is.

If the feed time is over two minutes, there is not a big difference in the number of leaning occurrences, but the time for treating the process extends. Therefore, it is desirable that the feed time be limited up to two minutes.

Further, the drying liquid 410 fed to the substrate W desirably has a temperature greater than or equal to 50° C. and less than a boiling point thereof.

Under the experiments, the higher the temperature of the drying liquid 410 is, the less the leaning occurs, but if the drying liquid 410 is boiled, bad influences such as deformation of patterns on the substrate may appear.

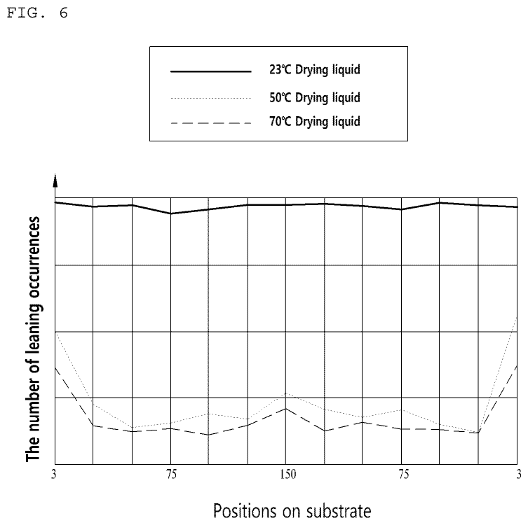

FIG. 6 is a graph showing comparison results of the number of leaning occurrences in cases where the drying liquid 410 fed through the drying liquid injection nozzle 450 has temperatures of 23, 50, and 70° C. respectively.

As shown, in the case where the temperature of the drying liquid 410 is greater than or equal to 50° C., the number of leaning occurrences decreases.

Further, the moving speed of the drying liquid injection nozzle 450 from the central portion to the peripheral portion of the substrate W desirably becomes fast gradually, thereby reducing the time for treating the process and increasing the productivity thereof.

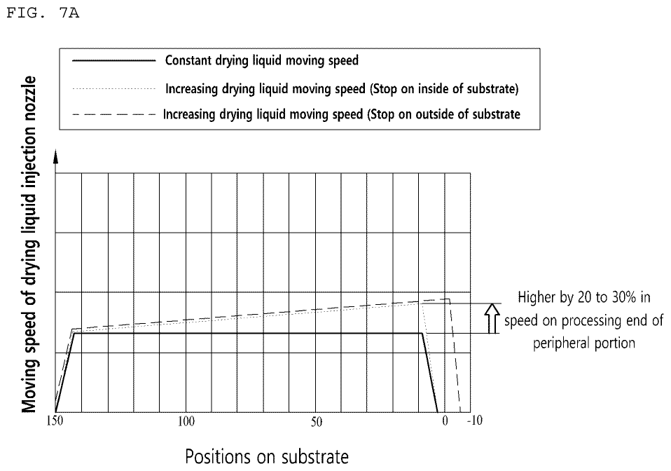

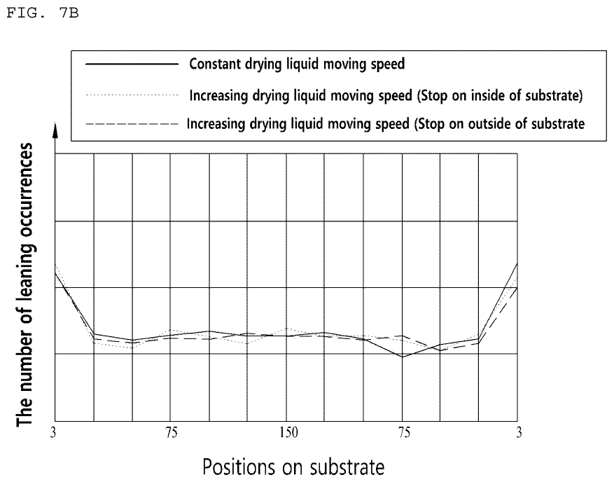

For example, FIG. 7A is a graph showing variations in a transversely moving speed of the drying liquid injection nozzle 450 over the substrate W. There are examples where the speed of the drying liquid injection nozzle 450 is constant, where it stops on the inside of the substrate W, while the moving speed is linearly increasing, and where it stops on the outside of the substrate W, while the moving speed is linearly increasing.

Further, FIG. 7B is a graph showing variations in the number of leaning occurrences according to changes in the moving speed of the drying liquid injection nozzle 450 from the central portion to the peripheral portion of the substrate W as shown in FIG. 7A, and in this case, even if the moving speed of the drying liquid injection nozzle 450 from the central portion to the peripheral portion of the substrate W is set to gradually increase, there are no variations in the number of leaning occurrences, thereby making it possible to reduce the time for treating the process.

Specifically, even if the speed of the drying liquid injection nozzle 450 linearly increases in the range of 20% to 30% at the processing end near the periphery portion of the substrate with respect to the constantly set moving speed, which is operation setting speed, of the drying liquid injection nozzle 450, the number of leaning occurrences is rarely varied.

While the drying liquid injection nozzle 450 is moving from the central portion to the peripheral portion of the substrate W, further, a flow rate of the drying liquid 410 discharged when the drying liquid injection nozzle 450 reaches the peripheral portion of the substrate W is desirably in the range of 50 to 80% of a flow rate of the drying liquid 410 discharged when the drying liquid injection nozzle 450 is located on the central portion of the substrate W, thereby reducing an amount of drying liquid 410 used and lowering a cost for operating equipment.

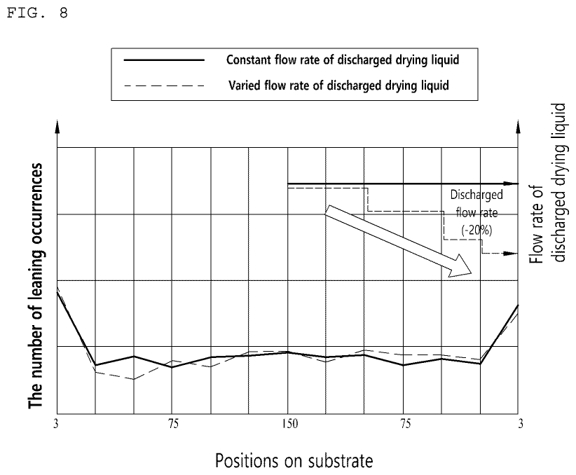

For example, FIG. 8 is a graph showing comparison results of the variations in the number of leaning occurrences in the case where a flow rate of the drying liquid 410 discharged when the drying liquid injection nozzle 450 is located the central portion of the substrate W and a flow rate of the drying liquid 410 discharged when the drying liquid injection nozzle 450 reaches on the peripheral portion of the substrate W are constant and the case where the flow rate of the drying liquid injection nozzle 450 from the central portion to the peripheral portion of the substrate W gradually decrease, while the drying liquid injection nozzle 450 is moving from the central portion to the peripheral portion of the substrate W.

As shown, the flow rate of the drying liquid 410 decreases in the form of stairs, but as long as the flow rate of the drying liquid 410 decreases gradually, it may have other shapes.

As shown, further, even if the flow rate of the drying liquid 410 fed to the peripheral portion of the substrate W decreases more than that fed to the central portion of the substrate W, there is no difference in the number of leaning occurrences on the substrate W compared to the case where the drying liquid discharge flow rate is constant in radial direction of the substrate W, and therefore, it is found that the amount of drying liquid used can be reduced, thereby decreasing the cost for operating the equipment.

To remove various types of foreign substances, first, the rinsing liquid 310 is fed to allow a relatively thin liquid film to be evenly applied to the entire top of the substrate W, while the rotational speed of the substrate W is being kept to a high speed of 200 to 1000 RPM. Next, the rinsing liquid 310 is supplied in a state that the rotational speed of the substrate W is reduced to a speed less than or equal to 100 RPM, thereby reducing the possibility of leaning occurrences.

In the state where the rotational speed of the substrate W is reduced to a speed less than or equal to 100 RPM, the rinsing liquid 310 forms a relatively thick liquid film on the entire top of the substrate W.

After that, the rotational speed of the substrate W is kept to a speed less than or equal to 300 RPM, and then, the drying liquid 410 is fed to the top of the substrate W, so that the replacement and drying are carried out.

In detail, after the drying liquid injection nozzle 450 has been located on the central portion of the substrate W, while the rotational speed of the substrate W is being kept to a speed less than or equal to 100 RPM, the rinsing liquid 310 is replaced with the drying liquid 410. In this case, the centrifugal force of the substrate W becomes small due to such a low rotational speed, so that the influence on the surface tension of the drying liquid 410 becomes less, thereby minimizing the number of leaning occurrences.

In more detail, while the rotational speed of the substrate W is being kept to a low speed less than or equal to 100 RPM, the drying liquid 410 is fed to the top of the substrate W where the relatively thick liquid film of the rinsing liquid 310 is formed, and thus, the drying liquid 410 replaces the rinsing liquid 310 over the entire region from the central portion to the peripheral portion of the substrate W, thereby minimizing the number of leaning occurrences and completing the replacement. Under such a low rotational speed of the substrate W, the drying liquid 410 replacing the rinsing liquid 310 is formed as a relatively thick liquid film on the substrate W.

Next, the rotational speed of the substrate W whose replacement is completed increases to a relatively high speed greater than 100 RPM and less than or equal to 300 RPM, and thus, the rinsing liquid droplets, which are not discharged yet from the gap of a capacitor, are removed using the centrifugal force of the substrate W.

That is, if the rotational speed of the substrate W increases to a relatively high speed greater than 100 RPM and less than or equal to 300 RPM, the remaining rinsing liquid is completely removed, but if the rotational speed of the substrate W excessively increases over the above speed, the capacitor falls to cause leaning.

As a result, increasing the rotational speed of the substrate W to a relatively high speed greater than 100 RPM and less than or equal to 300 RPM allows the rinsing liquid 310 and the drying liquid 410 remaining between patterns to be completely removed, thereby having no influence on the occurrences of leaning on the patterns.

In the state where the rotational speed of the substrate W is kept to 100 RPM to 300 RPM, if the drying liquid injection nozzle 450 moves from the central portion to the peripheral portion of the substrate W to feed the drying liquid 410 to the substrate W, the dried region 800 extending gradually from the central portion is formed.

The formation of the dried region 800 is accelerated as the substrate W is heated through the heating unit 500 located thereunder, thereby shortening the time for treating the process.

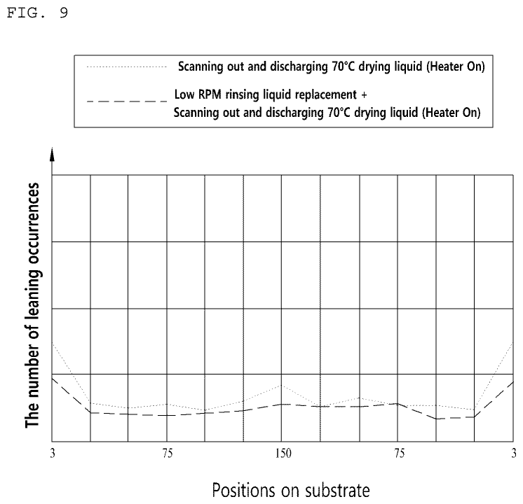

FIG. 9 is a graph showing the comparison results of the number of leaning occurrences in the case where the drying liquid 410 is fed, while the substrate W is rotating to a low rotational speed less than or equal to 100 RPM and in the case where the drying liquid 410 is fed, while the substrate W is rotating to a high rotational speed greater than or equal to 500 RPM, after the treatment of the rinsing liquid 310. Such both comparison cases are made under the conditions where the drying liquid injection nozzle 450 moves from the central portion to the peripheral portion of the substrate W, while the drying liquid 410 having a temperature of 70° C. is being fed, and the substrate W is heated.

As shown, in the case where the drying liquid 410 is fed, while the substrate W is rotating to a low rotational speed less than or equal to 100 RPM, the number of leaning occurrences on the peripheral portion of the substrate W is substantially different from that on the peripheral portion of the substrate W in the case where the drying liquid 410 is fed, while the substrate W is rotating to a high rotational speed.

Further, as shown in FIG. 2, after the drying liquid injection nozzle 450 completely moves (scans out) to the peripheral portion of the substrate W, the power of the heating unit 500 is cut off, and until a substrate temperature falls, the substrate-holding unit 100 rotates for a given period of time and then stops. Next, stabilization of the substrate W is carried out, and then, the substrate W is taken out of the substrate-holding unit 100.

As described above, the substrate treatment apparatus and method according to the present disclosure is configured to have the drying liquid feed unit located to reciprocate horizontally above the substrate in such a way as to feed the drying liquid through the drying liquid injection nozzle, in a state where the entire top region of the substrate is covered with the rinsing liquid, to allow the rinsing liquid to be replaced with the drying liquid, and configured to have the heating unit located under the substrate to heat the substrate, so that upon cleaning of the substrate, the number of leaning occurrences can be remarkably reduced.

Further, the substrate treatment apparatus and method according to the present disclosure is configured to allow the drying liquid to be fed through the drying liquid injection nozzle and replace the rinsing liquid, while the substrate is being heated, and configured to allow the drying liquid injection nozzle to move from the central portion to the peripheral portion of the substrate, while feeding the drying liquid to the substrate whose replacement with the drying liquid is completed, so that the dried region extending from the central portion of the substrate can be exposed to the outside, thereby reducing the number of leaning occurrences through perfect dry having no residual liquid.

Furthermore, the substrate treatment apparatus and method according to the present disclosure is configured to allow the rinsing liquid to be fed to the substrate by means of the rinsing liquid feed unit, while the substrate is being heated by the heating unit, so that the rinsing liquid can be mixed smoothly with the drying liquid in next replacement process and the volatile reaction can occur more quickly, thereby reducing the time for treating the process.

Moreover, the substrate treatment apparatus and method according to the present disclosure is configured to allow the drying liquid injection nozzle to feed the drying liquid, in the state of being stopped on the central portion of the substrate for a given period of time, e.g., 10 seconds or more, so that after the replacement of the rinsing liquid with the drying liquid is perfectly completed, the drying liquid injection nozzle can move from the central portion to the peripheral portion of the substrate, thereby greatly reducing the number of leaning occurrences.

Further, the substrate treatment apparatus and method according to the present disclosure is configured to allow the drying liquid fed to the substrate to have a temperature greater than or equal to 50° C. and less than a boiling point thereof, thereby expecting leaning reduction effects.

Besides, the substrate treatment apparatus and

method according to the present disclosure is configured to allow the moving speed of the drying liquid injection nozzle from the central portion to the peripheral portion of the substrate to become gradually fast, thereby reducing the time for treating the process and increasing the productivity thereof.

Furthermore, the substrate treatment apparatus and method according to the present disclosure is configured to allow a flow rate of the drying liquid discharged when the drying liquid injection nozzle reaches the peripheral portion of the substrate to be lower than a flow rate of the drying liquid discharged when the drying liquid injection nozzle is located on the central portion of the substrate, while the drying liquid injection nozzle is moving from the central portion to the peripheral portion of the substrate, thereby reducing an amount of drying liquid used and lowering a cost for operating equipment.

Additionally, the substrate treatment apparatus and method according to the present disclosure is configured to allow the rotational speed of the substrate to be kept to a low speed less than or equal to 100 RPM, after the drying liquid injection nozzle has been located on the center of the substrate, to thus replace the rinsing liquid with the drying liquid, and then to allow the rotational speed of the substrate to increase to a relatively high speed greater than 100 RPM and less than or equal to 300 RPM to thus complete the replacement, thereby minimizing the number of leaning occurrences and achieving more fast replacement and drying in the process where the rinsing liquid formed as a relatively thick liquid film is replaced with the drying liquid.

The present disclosure may be modified in various ways and may have several exemplary embodiments. It is therefore intended that the scope of the disclosure be limited not by this detailed description, but rather by the claims appended hereto, and it should be understood that the disclosure covers all the modifications, equivalents, and replacements within the idea and technical scope of the disclosure.

What is claimed is:

1. A substrate treatment apparatus comprising:
a substrate-holding unit for holding and rotating a substrate;
a treatment liquid feed unit for feeding treatment liquid to a top of the substrate;
a rinsing liquid feed unit for feeding rinsing liquid to the top of the substrate;
a drying to reciprocate liquid feed unit located horizontally above the substrate in such a way as to feed drying liquid through a drying liquid injection nozzle, in a state where the entire top region of the substrate is covered with the rinsing liquid, to allow the rinsing liquid to be replaced with the drying liquid; and
a heating unit located under the substrate to heat the substrate.

2. The substrate treatment apparatus according to claim 1, wherein while the substrate is being heated by means of the heating unit, the drying liquid is fed to the substrate through the drying liquid injection nozzle to allow the rinsing liquid to be replaced therewith, and while the substrate on which the rinsing liquid has been replaced with the drying liquid is being heated, the drying liquid injection nozzle moves from a central portion to a peripheral portion of the substrate to feed the drying liquid to the substrate.

3. The substrate treatment apparatus according to claim 2, wherein while the substrate is being heated by means of the heating unit, the rinsing liquid is fed to the substrate by means of the rinsing liquid feed unit.

4. The substrate treatment apparatus according to claim 2, wherein after the drying liquid injection nozzle stops on the central portion of the substrate for a given period of time and feeds the drying liquid to the substrate to allow the rinsing liquid to be replaced with the drying liquid, the drying liquid injection nozzle moves from the central portion to the peripheral portion of the substrate.

5. The substrate treatment apparatus according to claim 4, wherein the time during which the drying liquid injection nozzle feeds the drying liquid to the substrate in the state where the drying liquid injection nozzle stops on the central portion of the substrate is in the range between 10 and 120 seconds.

6. The substrate treatment apparatus according to claim 1, wherein the drying liquid fed to the substrate has a temperature greater than or equal to 50° C. and less than a boiling point thereof.

7. The substrate treatment apparatus according to claim 1, wherein the moving speed of the drying liquid injection nozzle from the central portion to the peripheral portion of the substrate becomes gradually fast.

8. The substrate treatment apparatus according to claim 1, wherein while the drying liquid injection nozzle is moving from the central portion to the peripheral portion of the substrate, a flow rate of the drying liquid discharged when the drying liquid injection nozzle reaches the peripheral portion of the substrate is in the range of 50 to 80% of a flow rate of the drying liquid discharged when the drying liquid injection nozzle is located on the central portion of the substrate.

9. A substrate treatment method comprising:
feeding treatment liquid to a top of a substrate rotating;
treating the top of the substrate with rinsing liquid;
feeding drying liquid to the substrate through a drying liquid injection nozzle, while the substrate is being heated in a state where the entire top region of the substrate is covered with the rinsing liquid, to allow the rinsing liquid to be replaced with the drying liquid; and
while the substrate on which the rinsing liquid has been replaced with the drying liquid is being heated, moving the drying liquid injection nozzle from a central portion to a peripheral portion of the substrate to feed the drying liquid to the substrate.

10. The substrate treatment method according to claim 9, wherein in treating the top of the substrate with rinsing liquid, the rinsing liquid is fed, while the substrate is being heated.

11. The substrate treatment method according to claim 9, wherein after the drying liquid injection nozzle stops on the central portion of the substrate for a given period of time, while feeding the drying liquid to the substrate, the drying liquid injection nozzle moves from the central portion to the peripheral portion of the substrate.

12. The substrate treatment method according to claim 11, wherein the time during which the drying liquid injection nozzle feeds the drying liquid to the substrate in the state where the drying liquid injection nozzle stops on the central portion of the substrate is in the range between 10 and 120 seconds.

13. The substrate treatment method according to claim 9, wherein the drying liquid fed to the substrate has a temperature greater than or equal to 50° C. and less than a boiling point thereof.

14. The substrate treatment method according to claim 9, wherein the moving speed of the drying liquid injection nozzle from the central portion to the peripheral portion of the substrate becomes gradually fast.

15. The substrate treatment method according to claim 9, wherein while the drying liquid injection nozzle is moving from the central portion to the peripheral portion of the substrate, a flow rate of the drying liquid discharged when the drying liquid injection nozzle reaches the peripheral portion of the substrate is in the range of 50 to 80% of a flow rate of the drying liquid discharged when the drying liquid injection nozzle is located on the central portion of the substrate.

16. The substrate treatment method according to claim 9, wherein the treating the top of the substrate with rinsing liquid is carried out to feed the rinsing liquid to the substrate and rinse the substrate, while a rotational speed of the substrate is being kept to a speed of 200 to 1000 RPM, and then to feed the rinsing liquid in a state where the rotational speed of the substrate decreases to a speed less than or equal to 100 RPM, and the replacing the rinsing liquid with the drying liquid is carried out to feed the drying liquid to the top of the substrate, while the rotational speed of the substrate is being kept to a speed less than or equal to 300 RPM.

17. The substrate treatment method according to claim 16, wherein the replacing the rinsing liquid with the drying liquid is carried out to replace the rinsing liquid with the drying liquid, while the rotational speed of the substrate is being kept to a speed less than or equal to 100 RPM after the drying liquid injection nozzle has been located on the center of the substrate, and thus to complete the replacement, while the rotational speed of the substrate increases to a speed greater than 100 RPM and less than or equal to 300 RPM.
